(19) United States
(12) Patent Application Publication
(10) Pub. No.: US 2006/0267614 A1
(43) Pub. Date: Nov. 30, 2006

(54) Ceramic heater

(76) Inventors: Youn-seob Lee, Suwon-si (KR); Hyeung-gyu Lee, Seoul (KR); Seung-An You, Seoul (KR)

Correspondence Address: MCNAIR LAW FIRM, P.A., P.O. BOX 10827, GREENVILLE, SC, 29603-0827, US

(21) Appl. No.: 11/363,663

(22) Filed: Feb. 27, 2006

(30) Foreign Application Priority Data
May 24, 2005 (KR) 10-2005-0043478
Sep. 8, 2005 (KR) 10-2005-0083532

(51) Int. Cl. G01R 31/02

(52) U.S. Cl. 324/760

(57) ABSTRACT

This invention is about a Ceramic Heater which comprises a built-in heating unit circuit and a built-in separate temperature sensor circuit, wherein precision circuit printing technology and layering technology are used, and which is manufactured by means of cofiring process. This invention is featured by a first circuit board, a heating circuit in certain patterns on the top side of the aforesaid first board, a sensor circuit positioned between the patterns of the heating circuit, and a second board which is layered over the aforesaid first board.

### FIELD OF THE INVENTION

This invention relates to a ceramic heater. More specifically, this invention relates to a ceramic heater which comprises a built-in heating circuit and a built-in temperature sensor circuit and which is manufactured by means of a cofiring process, wherein a precision circuit forming technology such as screen-printing, photolithography and layering technologies is used.

### BACKGROUND OF THE INVENTION

In existing prior art, in ceramic heaters that are composed simply of a heating circuit, the temperature of the ceramic heaters is controlled by analogue or digital means. Accordingly, the existing method of controlling the temperature of the heater has the following problems:

First, the analogue method reads the changes of the resistance value to detect the temperature according to the temperature of the heating circuit itself, but there is a problem in that it cannot raise the temperature quickly because the changing of the voltage and the reading of the resistance value are switched alternately.

Moreover, there is a high possibility that the switching circuit becomes defective in operation. Therefore, if the switching circuit malfunctions, the temperature is not detected and the heater can be overheated, which can cause damage to the heater. Thus, the prior art device has problems of slow heating and/or overheating which can be caused by the malfunctioning of the switching circuit.

Second, the digital method uses an exterior temperature sensor which is attached outside, wherein there are large differences in temperature sensing depending upon the positions of, and attachment methods for, the exterior temperature sensor making it very difficult to precisely control the temperature.

### SUMMARY OF THE INVENTION

To solve the problems of the existing technology as mentioned, this invention comprises a built-in heating circuit and a built-in temperature sensor circuit. The ceramic heater of this invention is manufactured by means of a cofiring process by using a precision circuit forming technology and layering technology such as screen-printing or photolithography wherein both the photolithographed circuit and the ceramic board are fired at the same time.

Other objectives of the invention are to manufacture a heating circuit which is composed of a material or materials whose heating performance is excellent and a temperature sensor circuit which is very sensitive to changes of temperature so that its temperature sensing performance is significantly improved. The temperature sensor circuit may be screen-printed or photolithographically formed onto a board of ceramic or metallic material or onto a board of mixture of ceramic and metal, e.g., a cermet material.

To solve the problems of the existing technology as mentioned above, an embodiment of this invention, a ceramic heater, comprises a first board, a heating circuit formed in defined patterns on a second board, a temperature sensor circuit positioned between the patterns of the heating circuit, the first board being layered over the second board.

Additionally, in another embodiment of this invention, a ceramic heater comprises a first board and a heating circuit formed in defined patterns on the top side of the first board with a temperature sensitive circuit, wherein the heating circuit and temperature sensor circuit comprise a ceramic heater.

### DESCRIPTION OF THE DRAWINGS

In the drawings attached hereto and made a part of this disclosure for purposes of illustration and not limitation:

FIG. 1 shows a first embodiment of the ceramic heater of the present invention having two boards; and,

FIG. 2 shows a second embodiment of the ceramic heater of the present invention having three boards.

### DETAILED DESCRIPTION

### Example 1

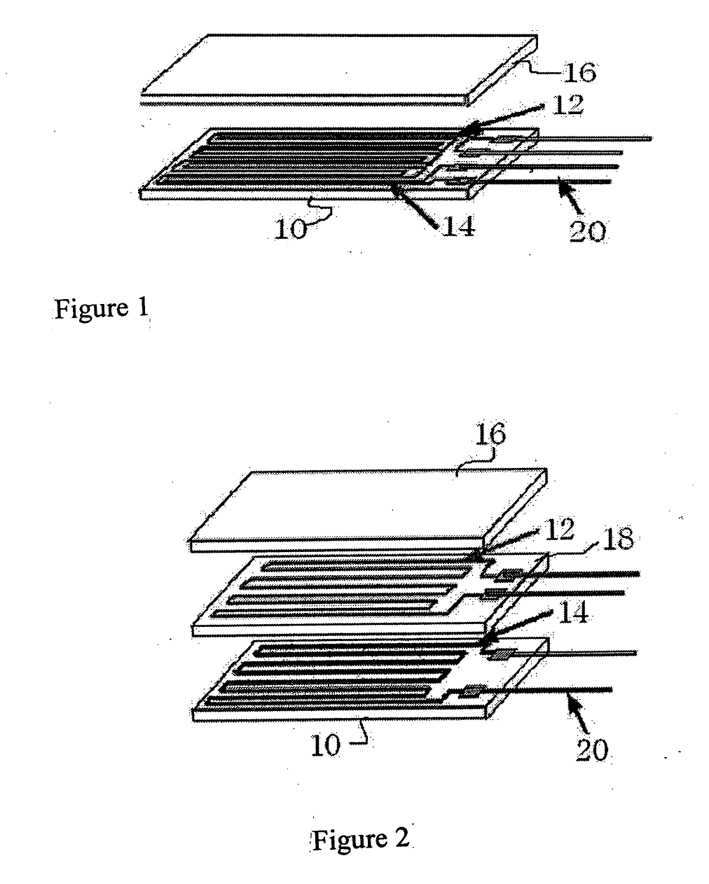

Referring to FIG. 1, the ceramic heater of a first embodiment of this invention comprises a first board 10, a heating circuit 14 in defined patterns on the top side of the first board 10, a temperature sensor circuit 12 positioned between the defined patterns of the heating circuit 14, and a second board 16 layered over the first board 10.

The aforesaid temperature sensor circuit 12 and heating circuit 14 are in patterns on the top side of board 10 wherein the temperature sensor circuit 12 and heating circuit 14 can be formed by means of screen-printing, or one pattern of either the temperature sensor circuit 12 or the heating circuit 14 can be formed on the top side of the first board 10 by means of a semiconductor process such as photolithography, and then the materials are plated onto the heating circuit or temperature sensor circuit, and the pattern of the remaining temperature sensor circuit or heating circuit is formed in the same manner on a second board 16 by means of photolithography.

Moreover, the aforesaid first board 10 and second board 16 are in rectangular plate form as illustrated in FIG. 1, which can be changed to various cubic, oval, circular, or parallelepiped structures and cylinder forms, so these boards can be applied to all forms or shapes of a ceramic heater. Number 20 on the drawing is connecting wire.

The ceramic heater of the structure as described above can have a temperature sensor circuit 12 positioned between the patterns of a heating circuit 14 to enable the temperature sensor circuit 12 to correctly sense the heating temperature so that the user can precisely control the heating temperature of the ceramic heater.

The aforesaid heating circuit 14 and temperature sensor circuit 12 receive electric power through wire 20 which is separately connected so as to heat, and then transmit the detected heating temperature to a controller (not illustrated in the drawing). As the wire 20 provides power to heating circuit, it results in the variation of resistance; and, then the temperature sensor circuit detects the variation of resistance and detects the temperature.

The aforesaid heating circuit 12 which may be used in this invention may be composed of Pt, W, Mo, Ni, Ta, SiC, MoSi₂ Ni—Cr alloy, Fe—Cr alloy or a synthetic of some or all of these materials, and the aforesaid temperature sensor circuit may be composed of Pt, W, Mo, Ni, Ta, SiC, MoSi₂ Ni—Cr alloy, Fe—Cr alloy or a synthetic of these materials, NTC (negative temperature coefficient) thermistor materials, PTC (positive temperature coefficient) thermistor materials, and synthetics and mixture of these materials, wherein the NTC thermistor materials are Mn, CO, Ni, Fe, etc. and the aforesaid PTC thermistor materials are BaTiO₃, Y, Ce, La, Sn, etc.

### Example 2

The embodiment of example 2 of this invention as illustrated in FIG. 2 of the attached drawing comprises a first board 10, a heating circuit 14 formed in a defined pattern on a second board 16, a middle board 18 layered over the first board 10, a temperature sensor circuit 12 formed on a middle board 18, and the second board 16 layered over the middle board 18.

The aforesaid heating circuit 14 and temperature sensor circuit 12 are in patterns on the top side of the first board 10 and the middle board 18 respectively. As seen in the embodiment of Example 1, the temperature sensor circuit 12 and the heating circuit 14 are formed by means of screen-printing or photolithographic plating.

Moreover, as illustrated in the first embodiment, the aforesaid first board 10, middle board 18 and the second board 16 are in rectangular plate form, as seen in the drawing, but they can be changed to various solid structures such as cubic or parallelepiped form and cylinder form. Therefore, the circuits can be applied to all shapes of ceramic heaters.

In the ceramic heater which has the aforesaid structure, the temperature sensor circuit 12 and heating circuit 14 are formed on their respective board 10 and 18, but the aforesaid heating circuit 14 receives electric power so as to heat through a wire 20 which is separately connected, and the temperature sensor circuit 12 transmits the detected heating temperature to the controller (not illustrated in the drawing) through the wire 20.

And unlike the first embodiment, the temperature sensor circuit 12 is positioned between the heating circuit 14 and the board 18, so it is not as directly affected by the heat generated by the heating circuit 14, which prevents any damage from the heat.

This invention with the structure, operation and desirable embodiment examples describe as above is effective in raising temperature very quickly and controlling it effectively by removing the switching process when applied to the analogue method for ceramic heaters and by fundamentally solving the problems which arise from the malfunction of the switching circuit which can cause overheating.

Additionally, this invention can measure the temperature data very precisely (within 3′) when applied to the digital method for ceramic heaters enabling the control of the temperature to be managed digitally, which is very effective in the precision control of temperatures.

This invention is not limited by these two embodiment examples, but can be changed in form by a person with ordinary skill in the art to which the invention pertains, which is included in the scope of the purpose of this invention described in the attached claims of this invention.

What is claimed is:

1. A ceramic heater comprising a first board; a second board layered over the first board; a heating circuit positioned between the first board and the second board in a defined pattern; and, a temperature sensor circuit positioned between the first board and second board.

2. The ceramic heater of claim 1, wherein the heating circuit is formed in deferred patterns on the top side of the first board and the temperature sensor circuit is formed between the patterns of the heating circuit.

3. The ceramic heater of claim 1, wherein the heating circuit is formed in defined patterns on the bottom side of the aforesaid second board, and the temperature sensor circuit is formed between the patterns of the heating circuit.

4. The ceramic heater of claim 1, wherein the aforesaid heating circuit and temperature sensor circuit are formed by means of screen-printing.

5. The ceramic heater of claim 1, wherein the aforesaid heating circuit and temperature sensor circuit are formed by means of photolithography and plating.

6. The ceramic heater of claim 1, wherein the aforesaid heating circuit comprises a material selection from the group consisting of Pt, W, Mo, Ni, Ta, SiC, MoSi₂ Ni—Cr alloy, Fe—Cr alloy and a synthetic of one of these materials.

7. The ceramic heater of claim 1, wherein the aforesaid temperature sensor circuit comprises a material selected from the group consisting of Pt, W, Mo, Ni, Ta, SiC, MoSi₂ Ni—Cr alloy, Fe—Cr alloy and a synthetic of any of the foregoing materials, NTC thermistor materials, namely, as Mn, CO, Ni, Fe, etc., PTC thermistor materials, namely, BaTiO₃, Y, Ce, La, Sn, and Pt and a synthetic of any of these materials.

8. The ceramic heater of claim 1, wherein the aforesaid first board and the second board on which the aforesaid heating circuit and temperature sensor circuit are formed are in plate form or cylinder form.

9. The ceramic heater of claim 1, including a first board, a middle board layered over the first board, a second board which is layered over the middle board, a heating circuit positioned between the first board and the second board, and a temperature sensor circuit positioned between the aforesaid first board and the second board.

10. The ceramic heater of claim 9, wherein the middle board is positioned between the first board and the second board and said heater comprises multiple layers.

11. The ceramic heater of claim 9, wherein the heating circuit formed in defined patterns on the top side of the first board, and the temperature sensor circuit which is formed on one side of the middle board in a manner not to face the top of the first board.

12. The ceramic heater as claimed in claim 9, wherein the heating circuit formed in defined patterns on the bottom side of the second board and the temperature sensor circuit is formed on one side of the middle board in a manner not to face the bottom of the second board.

13. The ceramic heater as claimed in claim 9, wherein the temperature sensor circuit formed in defined patterns on the top side of the first board, and the heating circuit is formed on one side of the middle board in a manner not to face the top of the first board.

14. The ceramic heater as claimed in claim 9, wherein the temperature sensor circuit formed in defined patterns on the bottom side of the second board and the heating circuit is formed on one side of the middle board in a manner not to face the bottom of the second board.

15. The ceramic heater as claimed in claim 9, wherein the heating circuit and temperature sensor circuit are formed by means of screen-printing.

16. The ceramic heater as claimed in claim 9, wherein the heating circuit and temperature sensor circuit are formed by means of photolithography and plating.

17. The ceramic heater as claimed in claim 9, wherein the heating circuit comprises a material selected from the group consisting of Pt, W, Mo, Ni, Ta, SiC, MoSi₂ Ni—Cr alloy, Fe—Cr alloy and a synthetic of all of these materials.

18. The ceramic heater as claimed in claim 9, wherein the temperature sensor circuit comprises a material selected from the group consisting of Pt, W, Mo, Ni, Ta, SiC, MoSi₂ Ni—Cr alloy, Fe—Cr alloy and a synthetic of all of these materials, NTC thermistor materials, namely, Mn, CO, Ni and Fe, PTC thermistor materials, namely, BaTiO₃, Y, Ce, La and Sn, and Pt and synthetics of all of these materials.

19. The ceramic heater as claimed in claim 9, wherein it is the first and second boards where the said temperature sensor circuit and temperature sensor circuit are formed are in plate form or cylinder form.
